(19) United States
(12) Patent Application Publication
(10) Pub. No.: US 2026/0153561 A1
(43) Pub. Date: Jun. 4, 2026

(54) SYSTEM ON CHIP AND DEBUGGING METHOD FOR SYSTEM ON CHIP

(71) Applicant: Samsung Electronics Co., Ltd., Suwon-si (KR)

(72) Inventor: Sung Hun KIM, Suwon-si (KR)

(73) Assignee: Samsung Electronics Co., Ltd., Suwon-si (KR)

(21) Appl. No.: 19/235,246

(22) Filed: Jun. 11, 2025

(30) Foreign Application Priority Data
Nov. 29, 2024 (KR) 10-2024-0174728

(51) Int. Cl. G01R 31/317; H03K 3/037

(52) U.S. Cl. CPC G01R 31/31724; G01R 31/31721; G01R 31/31727; H03K 3/037

(57) ABSTRACT

A system on chip (SoC) includes a plurality of blocks each including an input terminal and an output terminal and each including a plurality of synchronization circuits connected by a scan-chain, a test data in (TDI) line, a test data out (TDO) line connected to the output terminal, a test access port (TAP) controller to control an operation of the blocks based on a TDI signal, a TDO signal, a test clock (TCK) signal, a test reset (TRST) signal and a test mode select (TMS) signal, a power management unit to control power gating for the blocks, and a clock management unit to control a clock signal provided to the blocks. The TAP controller includes a first register that stores a first data for generating a first control signal controlling the power and clock management units, which control the operation of the blocks based on the first control signal.

### CROSS-REFERENCE TO RELATED APPLICATION

This U.S. non-provisional application claims priority under 35 U.S.C. § 119 to Korean Patent Application No. 10-2024-0174728 filed on Nov. 29, 2024, in the Korean Intellectual Property Office, the entire contents of which are herein incorporated by reference.

### BACKGROUND

Example embodiments relate to a system on chip and a debugging method for the system on chip.

JTAG is an industry standard established by the Joint Test Action Group to test a printed circuit board (PCB) and an integrated circuit chip (IC chip), and is codified in IEEE Standard 1149.1. A scan-dump method may perform debugging on a system on chip by repeating a same sequence when testing a same scenario after shifting-out values loaded into a scan-chain.

### SUMMARY

Example embodiments of the present disclosure provide a system on chip capable of performing debugging through a scan-dump method without adding a pad.

Example embodiments of the present disclosure are directed to a debugging method for a system on chip capable of performing debugging through a scan-dump method without adding a pad.

According to some example embodiments of the present disclosures, a system on chip includes a plurality of blocks each including an input terminal and an output terminal and each including a plurality of synchronization circuits connected by a scan-chain, a test data in (TDI) line, a test data out (TDO) line connected to the output terminal, a test access port (TAP) controller configured to control an operation of the plurality of blocks based on a TDI signal input to the TDI line, a TDO signal input to the TDO line, a test clock (TCK) signal, a test reset (TRST) signal and a test mode select (TMS) signal, a power management unit configured to control power gating for the plurality of blocks, and a clock management unit configured to control a clock signal provided to the plurality of blocks. The TAP controller includes a first register that is configured to store a first data for generating a first control signal that is configured to control the power management unit and the clock management unit, and the power management unit and the clock management unit are configured to control the operation of the plurality of blocks based on the first control signal received from the TAP controller.

According to some example embodiments of the present disclosures, a system on chip includes a plurality of blocks each including an input terminal and an output terminal and each including a plurality of synchronization circuits connected by a scan-chain, a power management unit configured to control power gating for the plurality of blocks, a clock management unit configured to control a clock signal provided to the plurality of blocks and a test access port (TAP) controller configured to control an operation of the plurality of blocks based on a test data in (TDI) signal synchronized with a test clock (TCK) signal and a test mode select (TMS) signal, and including a first register configured to store a first data for controlling the power management unit and the clock management unit. The TAP controller is configured to generate a first control signal for controlling the power management unit and the clock management unit based on the TMS signal and the first data, the power management unit is configured to turn on power provided to the plurality of blocks based on the first control signal, and the clock management unit is configured to stop a clock signal provided to the plurality of blocks based on the first control signal.

According to some example embodiments of the present disclosures, a debugging method for a system on chip includes a plurality of blocks each including an input terminal and an output terminal and each including a plurality of synchronization circuits connected by a scan-chain, the debugging method including receiving, by a test access port (TAP) controller, a debugging request signal, transmitting, by the TAP controller, a first control signal generated based on a test mode selection (TMS) signal and a first data to a power management unit and a clock management unit based on the debugging request signal, turning on power provided to the plurality of blocks based on the first control signal by the power management unit and stopping all clock signals provided to the plurality of blocks based on the first control signal by the clock management unit. The TAP controller includes a first register that stores first data for controlling the power management unit and the clock management unit.

According to some example embodiments, a system on chip includes a plurality of blocks each including an input terminal and an output terminal and each including a plurality of synchronization circuits connected by a scan-chain, an alive block configured to control operations of the plurality of blocks, the alive block including a power management unit configured to control power gating for the plurality of blocks, a clock management unit configured to control a clock signal provided to the plurality of blocks, and a test mode block including a latch circuit configured to receive a test mode enable signal from a first pad, and a selection circuit configured to receive a test reset signal from a second pad and provide an output to the latch circuit, and a Joint Test Action Group (JTAG) port configured to control an operation of the alive block based on a test data in (TDI) signal synchronized with a test clock (TCK) signal and a test mode select (TMS) signal, and including a first register configured to store a first data for generating a first control signal for controlling the power management unit and the clock management unit. The power management unit and the clock management unit are configured to control the operations of the plurality of blocks based on the first control signal received from the JTAG port. According to some example embodiments, the JTAG port further includes a second register that is configured to store a second data different from the first data, the JTAG port is configured to generate a second control signal for controlling the operation of the plurality of blocks based on the TDI signal and the second data, and the JTAG port is configured to select a target block to perform a scan-dump method from the plurality of blocks based on the second control signal. According to some example embodiments, the JTAG port further includes a third register that is configured to store a third data different from each of the first data and the second data, the JTAG port is configured to generate a third control signal for controlling the operation of the plurality of blocks based on the third data, and the JTAG port is configured to transmit a scan-dump enable signal for setting the plurality of blocks to a scan-dump mode to the plurality of blocks based on the third control signal. According to some example embodiments, the JTAG port is configured to shift out values loaded into the scan-chain of the target block based on the scan-dump enable signal, the JTAG port further includes a fourth register that stores a fourth data different from each of the first data, the second data and the third data, the JTAG port is configured to generate a fourth control signal for controlling the operation of the target block based on the fourth data, and the JTAG port is configured to output the values shifted out from the scan-chain of the target block through the output terminal of the target block based on the fourth control signal.

According to some example embodiments, an electronic system includes a processor, and a computer readable storage medium communicably coupled to the processor. The processor is implemented as a system on chip and includes a plurality of blocks each including an input terminal and an output terminal and each including a plurality of synchronization circuits connected by a scan-chain, a test data in (TDI) line, a test data out (TDO) line connected to the output terminal, a test access port (TAP) controller configured to control an operation of the plurality of blocks based on a TDI signal input to the TDI line, a TDO signal input to the TDO line, a test clock (TCK) signal, a test reset (TRST) signal and a test mode select (TMS) signal, a power management unit configured to control power gating for the plurality of blocks, and a clock management unit configured to control a clock signal provided to the plurality of blocks. The TAP controller includes a first register that is configured to store a first data for generating a first control signal. The first control signal is configured to control the power management unit and the clock management unit. The power management unit and the clock management unit are configured to control the operation of the plurality of blocks based on the first control signal received from the TAP controller.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a schematic block diagram illustrating a JTAG unit having a scan-chain.

FIG. 2 is a diagram illustrating a system on chip according to some example embodiments.

FIG. 3 is a diagram illustrating an instruction register of the system on chip of FIG. 2 according to some example embodiments.

FIG. 4 is a diagram illustrating an instruction register set of the system on chip of FIG. 2 according to some example embodiments.

FIG. 5 is a diagram illustrating that values shifted out from a scan-chain of a target block of the system on chip of FIG. 2 are output through a JTAG interface according to some example embodiments.

FIG. 6 is a diagram illustrating a JTAG port of FIG. 2 according to some example embodiments.

FIG. 7 is a flow chart illustrating a debugging method for a system on chip according to some example embodiments.

FIGS. 8, 9, 10, 11, 12, and 13 are diagrams illustrating a debugging method for a system on chip of FIG. 7 according to some example embodiments.

FIG. 14 is a diagram illustrating an electronic system that includes a system on chip according to some example embodiments.

FIG. 15 is a diagram illustrating an electronic system that includes a system on chip according to some example embodiments.

### DETAILED DESCRIPTION OF EXAMPLE EMBODIMENTS

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

Hereinafter, a system on chip and a debugging method for the system on chip according to some example embodiments will be described with reference to the accompanying drawings.

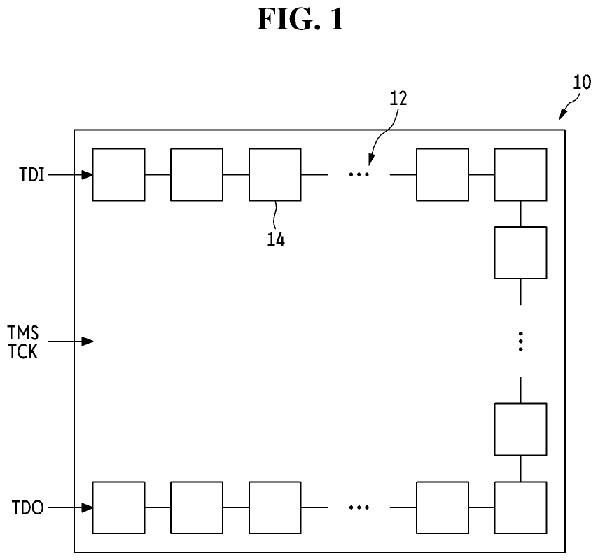

FIG. 1 is a schematic block diagram illustrating a JTAG unit 10 having a scan-chain.

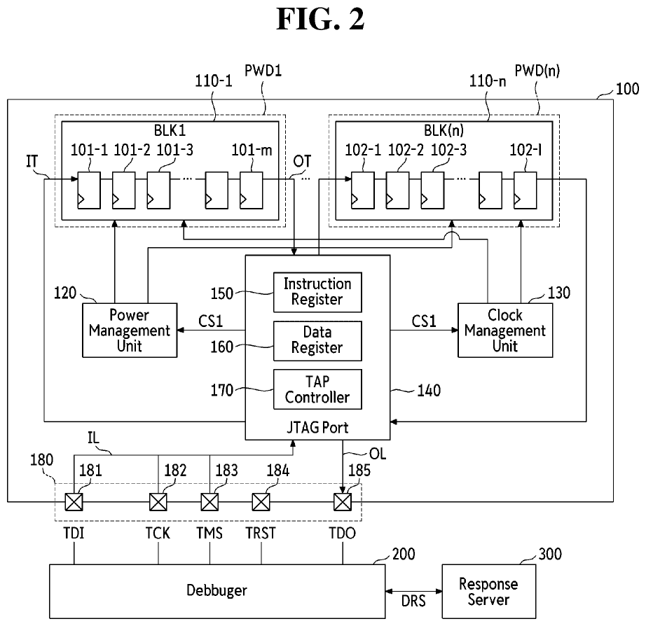

Referring to FIG. 1, the JTAG unit 10 may include a scan-chain 12 to which boundary-scan cells (BSC) 14 are connected. A test for a system on chip 100 (see FIG. 2), which includes the JTAG unit 10, may be performed by inputting a Test Data In (TDI) signal to the boundary scan cells 14.

A test clock (TCK) signal and a test mode select (TMS) signal may be signals for controlling the JTAG unit 10. The TCK signal and the TMS signal may be input to a Test Access Port (TAP) controller 170 (see FIG. 2) to control an operation of the JTAG unit 10. After the operation of the JTAG unit 10 is completed, a result of the operation may be output by the system on chip 100 as a Test Data Out (TDO) signal. In some example embodiments, the TMS signal and the TDI signal may be synchronized with the TCK signal.

For the purposes of discussion, a ‘signal’ may refer to a digital signal that may include 1-bit or more bits, or may also be referred to a data.

Such a JTAG unit 10 may be embedded in many kinds of integrated circuit chips and system on chips. For example, the JTAG unit 10 may be embedded in a microprocessor, a microcontroller, a complex programmable logic device (CPLD), a field programmable gate array (FPGA), and an application specific integrated circuit (ASIC). However, the current JTAG unit is a standard used not only for testing the inside of a chip but also for programming to a flash memory inside the chip. For example, the JTAG unit is used for FPGA image potting, etc.

FIG. 2 is a diagram illustrating a system on chip 100 according to some example embodiments.

Referring to FIG. 2, the system on chip 100 may include a plurality of blocks BLK1 to BLK(n), labelled as 110-1 to 110-n, respectively, a JTAG interface 180, a JTAG port 140, a power management unit 120, and a clock management unit 130.

The plurality of blocks 110-1 to 110-n may be functional blocks of a system on chip (where ‘n’ is an integer of 2 or more). Each of the plurality of blocks 110-1 to 110-n may be on-chip logic to be tested for debugging, and may be referred to as a core logic or unit under test.

For the sake of brevity of discussion, block 110-1 is described below, and the description of block 110-1 is equally applicable to blocks 110-2 to 110-n.

The block 110-1 may include an input terminal IT and an output terminal OT, and may include a plurality of synchronization circuits 101-1 to 101-m connected by one scan-chain (where ‘m’ is an integer of 2 or more).

Each of the plurality of synchronization circuits 101-1 to 101-m, which are sequentially connected, may be, for example, one scan flip-flop. An output terminal of a current (or given) scan flip-flop may be connected to an input terminal of next (or subsequent) scan flip-flop. The current scan flip-flop may transmit a stored value to the next flip-flop based on the TCK signal and the TMS signal in a scan test mode and/or a scan dump mode. Each scan flip-flop includes an input terminal and an output terminal, and a combination logic may be included between the output terminal of the current scan flip-flop and the input terminal of the next scan flip-flop.

Each of the plurality of synchronization circuits 101-1 to 101-m may be a digital circuit that may operate in synchronization with the TCK signal, and may be implemented as a flip-flop or a scan flip-flop. For example, each of the plurality of synchronization circuits 101-1 to 101-m may operate based on the TCK signal and the TMS signal.

The JTAG unit 10 of FIG. 1 may correspond to one of the plurality of blocks 110-1 to 110-n of FIG. 2, and each of the boundary scan cells 14 of FIG. 1 may correspond to each of the synchronization circuits 101-1 to 101-m of FIG. 2.

A JTAG interface 180 is a special 4-pin interface or 5-pin interface added to the system on chip 100. The JTAG interface 180 may include a TDO pin 185, a TCK pin 182, a TDI pin 181, and a TMS pin 183, and may optionally further include a Test Reset (TRST) pin 184.

Pins 181 to 185 of the JTAG interface 180 and signals input and output through the pins 181 to 185 will be understood with reference to the Institute of Electrical and Electronics Engineers (IEEE) 1149.1 standard. Although the term ‘pin’ is used in the present disclosure, the pin may refer to a pad or ball, which may indicate an external interface of the chip.

The JTAG port 140 may include a TAP controller 170, an instruction register 150, and a data register 160. The JTAG port 140 is an IEEE 1149.1 standard JTAG port. 1-bit data transmitted from the TDI pin 181 may be written serially in the plurality of synchronization circuits 101-1 to 101-m connected by one scan-chain through the JTAG port 140 for each rising edge of the TCK signal. Also, 1-bit data read serially from the plurality of synchronization circuits 101-1 to 101-m connected by one scan-chain may be output to the TDO pin 185 through the JTAG port 140 for each rising edge of the TCK signal.

The TAP controller 170 may control the operation of each of the plurality of blocks 110-1 by using the TDO signal TDO, the TCK signal TCK, the TDI signal TDI, the TRST signal TRST, and the TMS signal TMS.

Each module inside the system on chip 100 may expose or include a test access port (TAP). Accordingly, a response server 300 may manipulate, modify, or control the TMS signal and the TDI signal together with the TCK signal through the JTAG port 140, and may read the result value through the TDO pin 185 to perform communication with the TAP. In some example embodiments, the response server 300 may be a host of the system on chip 100.

Each JTAG port 140 may include a single instruction register 150 and a plurality of data registers 160. The number of bits of the data register 160 may vary for each JTAG port 140. The data registers 160 may be combined through the TDI signal and the TDO signal to form a shift register.

An input terminal IT of the block 110-1 may be connected to the TDI pin 181 through a TDI line IL and the JTAG port 140, and an output terminal OT of the block 110-1 may be connected to the TDO pin 185 through a TDO line OL and the JTAG port 140.

The power management unit 120 may perform a power management operation for a plurality of blocks, units and modules included in the system on chip 100. In some example embodiments, the power management operation may refer to an operation of controlling a power source supplied to a specific or given circuit or device. For example, the power management unit 120 may perform a power management operation for a plurality of blocks, units and modules included in the system on chip 100 through power-gating using a power transistor.

Referring to FIG. 2, the system on chip 100 may be divided into a plurality of power domains PWD1 to PWD(n). For example, the block BLK1 may operate in the first power domain PWD1, and the block 110-n may operate in the n^{th} power domain PWD(n). The plurality of blocks 110-1 to 110-n included in the system on chip 100 may correspond to different power domains, respectively. Accordingly, the power management unit 120 may individually manage the power source supplied to each of the plurality of blocks 110-1 to 110-n. For example, the power management unit 120 may turn on the power source of at least one of the plurality of blocks 110-1 to 110-n, may turn off the power source of other blocks, and/or may reduce the power supplied to other blocks. In addition or alternatively, the power management unit 120 may turn on the power source to one or more of the plurality of blocks 110-1 to 110-n, may turn off the power source to one or more of the plurality of blocks 110-1 to 110-n, and/or or may reduce the power supplied to one or more of the plurality of blocks 110-1 to 110-n.

For example, the TAP controller 170 may transmit a first control signal CS1 for managing the power source provided to each of the plurality of blocks 110-1 to 110-n to the power management unit 120 based on at least one of the TDO signal TDO, the TCK signal TCK, the TDI signal TDI or the TMS signal TMS, which is received from the JTAG port 140, and the power management unit 120 may individually manage the power source provided to each of the plurality of power domains PWD1 to PWD(n) based on the first control signal CS1 received from the JTAG port 140.

Although FIG. 2 illustrates that the power domain of the system on chip 100 includes a single block, example embodiments are not limited thereto. For example, the system on chip 100 may further include one or more other elements in addition to the elements shown in FIG. 2, and may further include a power domain that may include the one or more other elements. Alternatively, or in addition, the power domain may include more than one block.

The clock management unit 130 may control a clock signal provided to the plurality of blocks 110-1 to 110-n. For example, the TAP controller 170 may transmit a first control signal CS1 for managing the clock signal provided to each of the plurality of blocks 110-1 to 110-n based on at least one of the TDO signal TDO, the TCK signal, the TDI signal TDI, or the TMS signal, which is received from the JTAG interface 180, and the clock management unit 130 may individually manage the clock signal provided to each of the plurality of blocks 110-1 to 110-n based on the first control signal CS1 received from the JTAG port 140.

A debugger 200 may transmit a debugging request signal DRS to the JTAG port 140. The debugging request signal DRS may include a TDI signal, a TCK signal, a TRST signal, and/or a TMS signal. The JTAG port 140 may receive JTAG signals such as the TDI signal, the TCK signal, the TRST signal, and/or the TMS signal from the debugger 200. Also, the TDO signal processed in the JTAG port 140 may be output to the debugger 200 through the TDO pin 185.

The response server 300 may be a host that allows the debugger 200 to perform debugging for the system on chip 100. Although FIG. 2 illustrates that the response server 300 is separated from the debugger 200, the response server 300 may be included in the debugger 200, in some example embodiments.

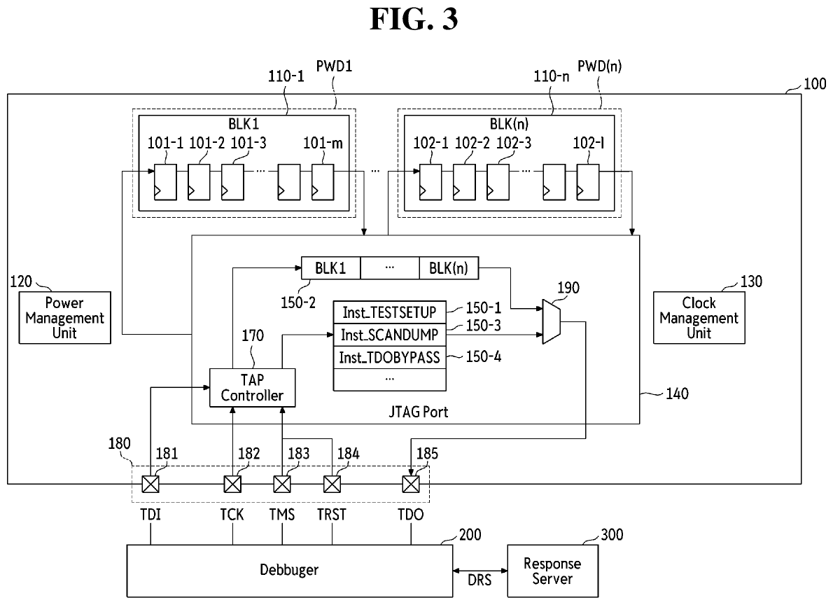

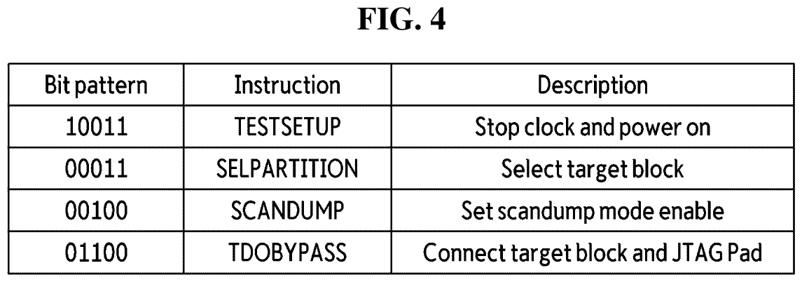

FIG. 3 is a diagram illustrating the instruction register 150 of the system on chip of FIG. 2. FIG. 4 is a diagram illustrating an instruction register set of the system on chip of FIG. 2. Hereinafter, the instruction register included in the JTAG port 140 of FIG. 2 will be described with reference to FIGS. 3 and 4.

FIG. 3 illustrates that a plurality of instruction registers 150-1, 150-2, 150-3 and 150-4 are included in the JTAG port 140 for convenience of illustration, but each JTAG port 140 may include a single instruction register 150 as described with reference to FIG. 2. Hereinafter, it is assumed that all of a TESTSETUP instruction register 150-1, a SELPARTITION instruction register 150-2, a SCANDUMP instruction register 150-3, and a TDOBYPASS instruction register 150-4 are included in one JTAG port 140.

Instructions for the TAP controller 170 to perform debugging for the system on chip 100 may be stored in each of the instruction registers 150-1, 150-2, 150-3 and 150-4 in the form of bit-type data (or a bit pattern) in response to a debugging request of the response server 300. For example, the TAP controller 170 may determine a debugging method based on the TDO signal, the TCK signal, the TDI signal and/or the TMS signal (optionally, the TRST signal), which are received from the JTAG interface 180, and may generate a control signal based on data stored in the instruction register 150 and the data register 160 in accordance with the determined debugging method, thereby performing a debugging operation for the plurality of blocks 110-1 to 110-n.

The TESTSETUP instruction register 150-1 may store data instructing to stop all clock signals provided to the plurality of blocks 110-1 to 110-n and to completely turn on the power source provided to the plurality of blocks 110-1 to 110-n. The TESTSETUP instruction register 150-1 may have a bit pattern of ‘10011’.

The SELPARTITION instruction register 150-2 may store data instructing to select a target block for debugging from the plurality of blocks 110-1 to 110-n. The SELPARTITION instruction register 150-2 may have a bit pattern of ‘00011’.

The SCANDUMP instruction register 150-3 may store data instructing to transmit a scan-dump enable signal to the plurality of blocks 110-1 to 110-n. In some example embodiments, the scan-dump enable signal may be a signal for setting the plurality of blocks 110-1 to 110-n to a scan-dump mode. In some example embodiments, when the scan-dump enable signal is applied to each of the plurality of blocks 110-1 to 110-n, values loaded into a scan-chain included in each of the plurality of blocks 110-1 to 110-n may be shifted out. The SCANDUMP instruction register 150-3 may have a bit pattern of ‘00100’.

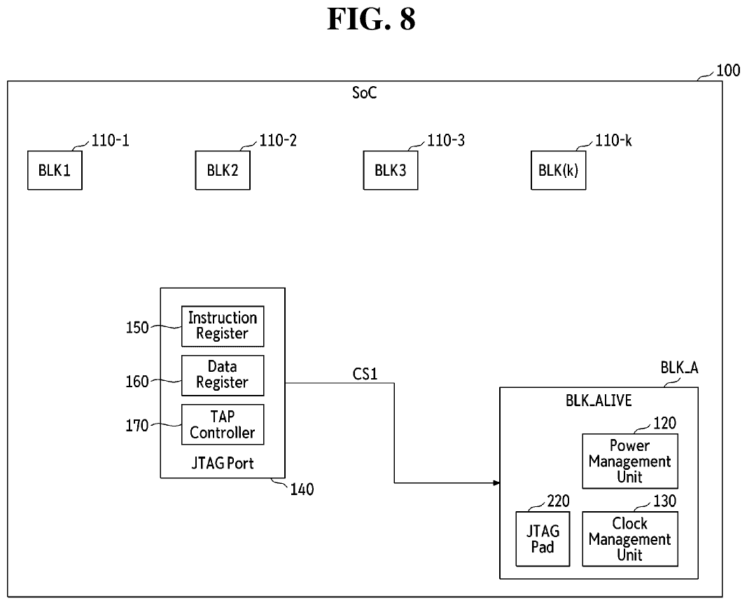

The TDOBYPASS instruction register 150-4 may store data instructing to connect the target block of the plurality of blocks 110-1 to 110-n with a JTAG pad 220 (see FIG. 8). As the target block and the JTAG pad 220 are connected to each other by the TDOBYPASS instruction, the values shifted out from the scan-chain of the target block may be output externally from the system on chip 100 through the TDO pin 185. The TDOBYPASS instruction register 150-4 may have a bit pattern of ‘01100’.

The bit patterns of the respective instruction registers 150-1, 150-2, 150-3 and 150-4 shown in FIG. 4 are merely examples, and the bit patterns of the respective instruction registers 150-1, 150-2, 150-3 and 150-4 may vary depending on application and/or design.

Referring to FIG. 3, the JTAG port 140 may further include a selection circuit 190. The selection circuit 190 may receive signals from the SELPARTITION instruction register 150-2 and the other instruction registers 150-1, 150-3 and 150-4, respectively, and may select one of the received signals and output the selected signal from the system on chip 100 through the TDO pin 185. The selection circuit 190 may transmit, to the outside of the system on chip 100, data as to which one of the plurality of blocks 110-1 to 110-n is used as a target block to perform a debugging operation currently in the system on chip 100 or data as to which instruction stored in one of the instruction registers 150-1, 150-3 and 150-4 is being currently performed in the system on chip 100.

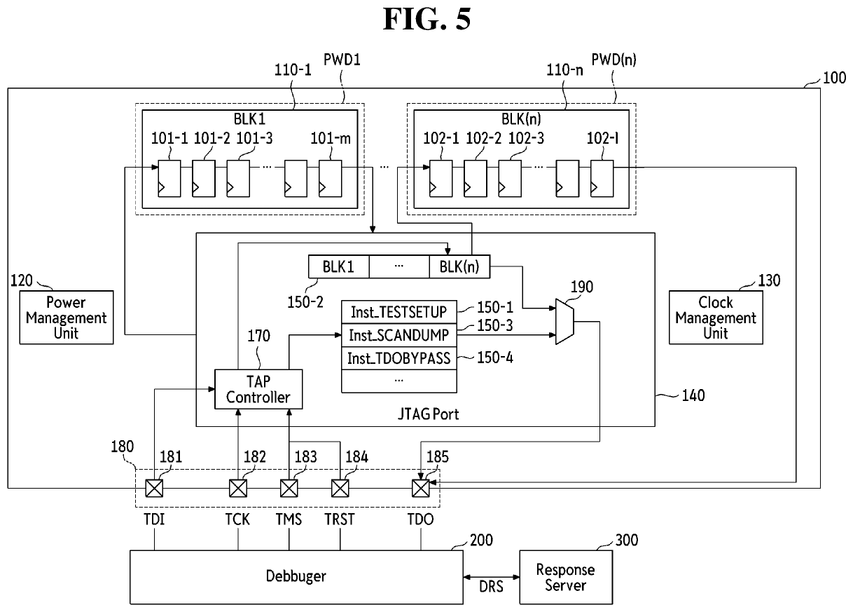

FIG. 5 is a diagram illustrating that values shifted out from a scan-chain of a target block of the system on chip of FIG. 2 are output through a JTAG interface. Hereinafter, a case that the block 110-n of the plurality of blocks 110-1 to 110-n is selected as a target block will be described as an example.

For example, the response server 300 may transmit a debugging request signal DRS to the system on chip 100 to allow the debugger 200 to select a block 110-n as a target block from the plurality of blocks 110-1 to 110-n included in the system on chip 100. The debugging request signal DRS may be transmitted to the TAP controller 170 in the form of a TDI signal through the TDI pin 181. The TAP controller 170 may select the block 110-n as a target block based on the received TDI signal. When block 110-n is selected as the target block, the values shifted out from the scan-chain of the block 110-n may be output externally from the system on chip 100 through TDO pin 185.

The data register 160 corresponding to the SELPARTITION instruction register 150-2 may store data corresponding to each of the plurality of blocks 110-1 to 110-n. For example, when it is assumed that each of the plurality of blocks 110-1 to 110-n stores 4-bit data and the total number of blocks included in the system on chip 100 is 30, the data register 160 corresponding to the SELPARTITION instruction register 150-2 may store 120-bit data.

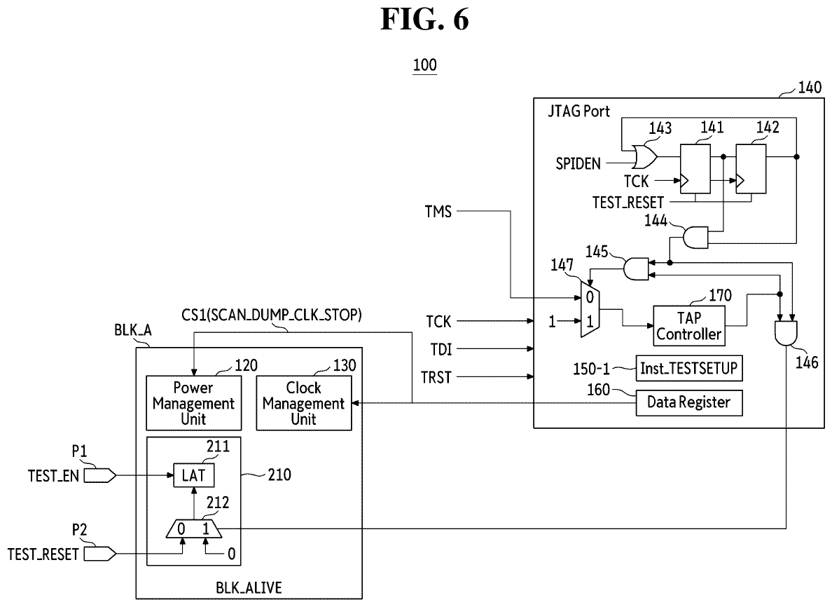

FIG. 6 is a diagram illustrating the JTAG port 140 of FIG. 2.

Referring to FIG. 6, the system on chip 100 may further include an alive block BLK_A. The alive block BLK_A may be a block that functions to control an operation of the plurality of blocks 110-1 to 110-n included in the system on chip 100. The alive block BLK_A may include a test mode block 210, the power management unit 120, and/or the clock management unit 130. The test mode block 210 may include a latch circuit 211 and a selection circuit 212. A test mode enable signal Test_EN may be input to the test mode block 210 through a first pad P1, and a test reset signal TEST_RESET may be input to a second pad P2. The test mode enable signal Test_EN may be input to the latch circuit 211, and the test reset signal TEST_RESET may be input to the selection circuit 212. The selection circuit 212 may selectively provide the test reset signal TEST_RESET or a signal ‘0’ to the latch circuit 211 in accordance with an output signal from a fourth circuit 146. The latch circuit 211 may store the test reset signal TEST_RESET or the signal ‘0’ in response to the test mode enable signal Test_EN. The latch circuit 211 may provide the stored signal to the JTAG interface 180. The JTAG interface 180 may provide the TMS signal, the TCK signal, the TDI signal, and the TRST signal to the JTAG port 140 in accordance with the signal received from the latch circuit 211.

The JTAG port 140 may include a TAP controller 170, a first circuit 143, a plurality of synchronization circuits 141 and 142, a second circuit 144, a third circuit 145, the fourth circuit 146, a selection circuit 147, a TESTSETUP instruction register 150-1, and a data register 160 corresponding to the TESTSETUP instruction register 150-1.

The first circuit 143 may be implemented as an OR gate. The first circuit 143 may receive a signal SPIDEN and an output signal of the second synchronization circuit 142. In some example embodiments, the signal SPIDEN may be a signal generated at a core site or the like so that an external user does not use a scan dump function by using the JTAG port 140. The signal output from the first circuit 143 may be input to the first synchronization circuit 141. The TCK signal input from the TCK pin 182 may be input to the first synchronization circuit 141. The first synchronization circuit 141 and the second synchronization circuit 142 may be sequentially connected. Each of the first synchronization circuit 141 and the second synchronization circuit 142 may be or include one flip-flop. An output terminal of the first synchronization circuit 141 may be connected to an input terminal of the second synchronization circuit 142. A value stored in the first synchronization circuit 141 may be transmitted to the second synchronization circuit 142 based on the TCK signal.

The output signal of the first synchronization circuit 141 and the output signal of the second synchronization circuit 142 may be input to the second circuit 144, respectively. The second circuit 144 may be implemented as an AND gate. The output signal of the second circuit 144 may be input to the third circuit 145 and the fourth circuit 146, respectively. The third circuit 145 and the fourth circuit 146 may be implemented as AND gates, respectively.

The selection circuit 147 may selectively provide the TMS signal received from the TMS pin 183 and a signal ‘1’ to the TAP controller 170 in accordance with the output signal from the third circuit 145. The TAP controller 170 may transmit the control signal to the third circuit 145 and the fourth circuit 146 in response to the signal received from the selection circuit 147. The output signal of the fourth circuit 146 may be provided to the selection circuit 212 of the alive block BLK_A.

The TAP controller 170 may execute an instruction stored in the TESTSETUP instruction register 150-1 based on the JTAG signals received from the JTAG interface 180. Accordingly, the TAP controller 170 may generate the first control signal CS1 based on data SCAN_DUMP_CLK_STOP stored in the data register 160 corresponding to the TESTSETUP instruction register 150-1, and may transmit the generated first control signal CS1 to the clock management unit 130 and the power management unit 120 of the alive block BLK_A.

The clock management unit 130 may stop all clock signals provided to the plurality of blocks 110-1 to 110-n in response to receiving the first control signal CS1. In addition, the power management unit 120 may completely turn on the power source provided to the plurality of blocks 110-1 to 110-n.

In this way, the TAP controller 170 may generate the first control signal CS1 for controlling the clock management unit 130 and the power management unit 120 based on the TMS signal and the data SCAN_DUMP_CLK_STOP stored in the data register 160.

According to some example embodiments, a signal for controlling the power management unit 120 and the clock management unit 130 during debugging for the target block may be generated by using the TESTSETUP instruction register 150-1 included in the JTAG port 140 and the data register 160 corresponding to the TESTSETUP instruction register 150-1 without the need to add other pads to the system on chip 100 in addition to the first pad P1 and the second pad P2.

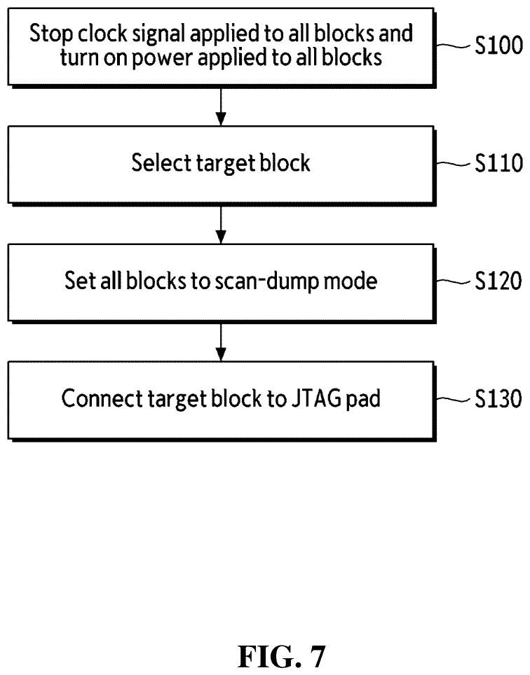

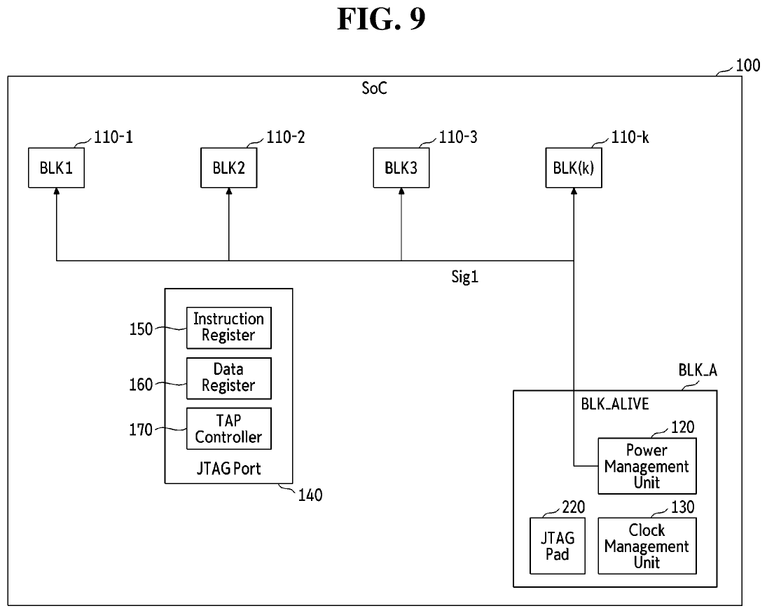

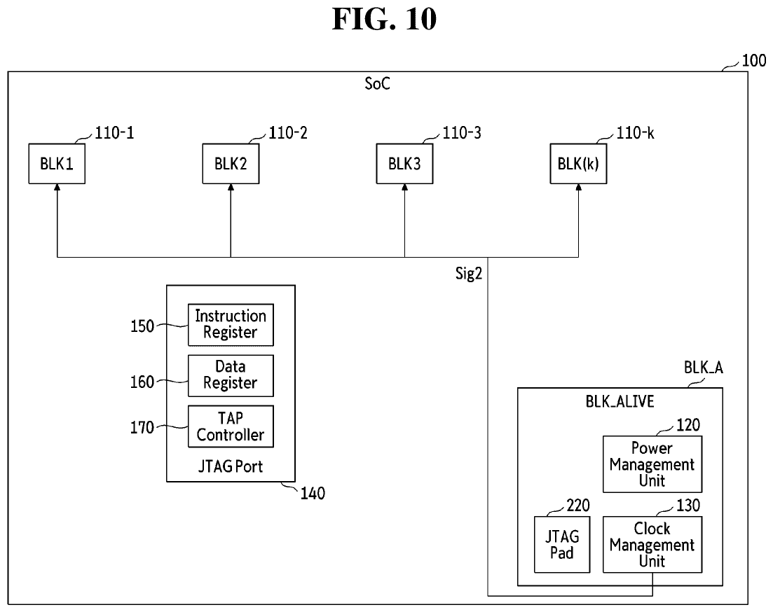

FIG. 7 is a flow chart illustrating a debugging method for a system on chip according to some example embodiments. FIGS. 8 to 13 are diagrams illustrating a debugging method for a system on chip of FIG. 7. It is understood that additional operations can be provided before, during, and after the operations in FIG. 7, and some of the operations described below can be replaced or eliminated, for additional embodiments of the method. The order of the operations/processes may be interchangeable, or two or more operations can be performed simultaneously. Hereinafter, a debugging method for a system on chip according to some example embodiments will be described with reference to FIGS. 7 to 13.

First, referring to FIG. 8, a TESTSETUP instruction may be stored in the instruction register 150, and data SCAN_DUMP_CLK_STOP corresponding to the TESTSETUP instruction may be stored in the data register 160. Based on the TMS signal TMS, and the data SCAN_DUMP_CLK_STOP stored in the data register 160, the TAP controller 170 may generate a first control signal CS1 and transmit the generated first control signal CS1 to the clock management unit 130 and the power management unit 120 of the alive block BLK_A.

The alive block BLK_A may further include a JTAG pad 220. The JTAG pad 220 may receive a signal output from an output terminal of a block selected as a target block from a plurality of blocks 110-1 to 110-k (where k is an integer of 2 or more) included in the system on chip 100. The JTAG pad 220 may transmit the received output signal to the TDO pin 185 in the form of a TDO signal.

Subsequently, referring to FIGS. 7, 9 and 10, the power management unit 120 may transmit a signal Sig1 for turning on the power source of the plurality of blocks 110-1 to 110-k to the plurality of blocks 110-1 to 110-k based on the first control signal CS1, and the clock management unit 130 may transmit a signal Sig2 for stopping the supply of the clock signal to the plurality of blocks 110-1 to 110-k based on the first control signal CS1 (S100).

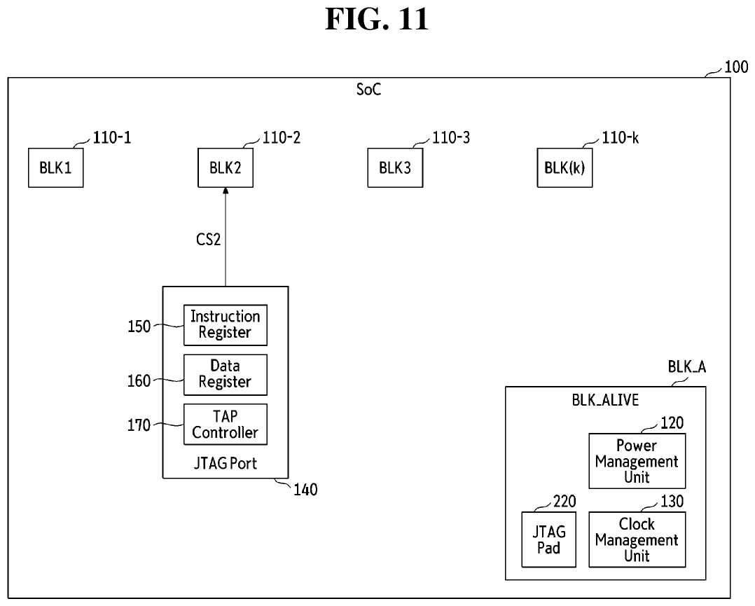

Subsequently, referring to FIGS. 7 and 11, the TAP controller 170 may select a target block to perform a scan-dump method from the plurality of blocks 110-1 to 110-k (S110). A SELPARTITION instruction may be stored in the instruction register 150, and data corresponding to the SELPARTITION instruction may be stored in the data register 160. The TAP controller 170 may generate a second control signal CS2 based on the TDI signal, and the data stored in the instruction register 150 and the data register 160, and the TAP controller 170 may select, for example, the block 110-2 as a target block based on the second control signal CS2.

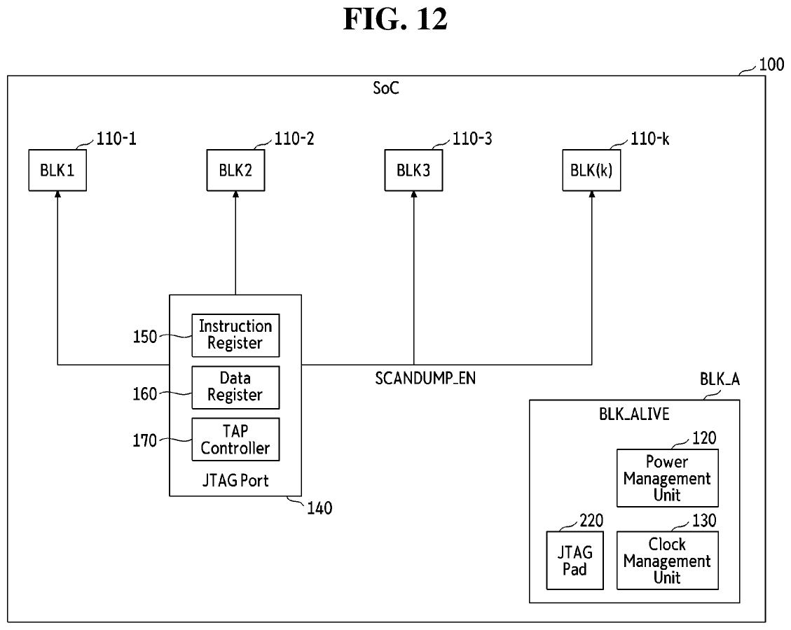

Subsequently, referring to FIGS. 7 and 12, the TAP controller 170 may set the plurality of blocks 110-1 to 110-k to a scan dump mode (S120). A SCANDUMP instruction may be stored in the instruction register 150, and data corresponding to the SCANDUMP instruction may be stored in the data register 160. The TAP controller 170 may generate a third control signal for setting the plurality of blocks 110-1 to 110-k to a scan-dump mode based on the data stored in the instruction register 150 and the data register 160, and the TAP controller 170 may transmit a scan-dump enable signal SCANDUMP_EN to the plurality of blocks 110-1 to 110-k based on the third control signal. Accordingly, the TAP controller may shift out values loaded into each scan-chain of the plurality of blocks 110-1 to 110-k including the target block 110-2.

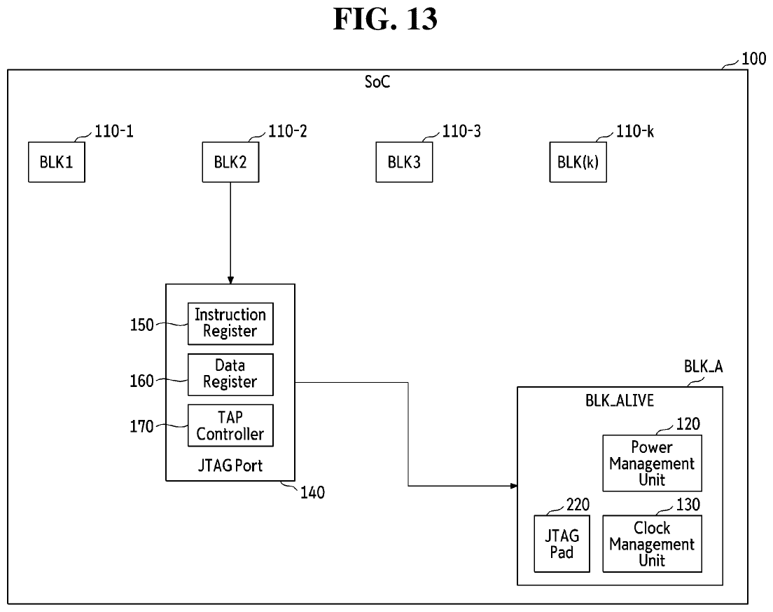

Subsequently, referring to FIGS. 7 and 13, the TAP controller 170 may connect the target block to the JTAG pad 220 (S130). Accordingly, values shifted out from the scan-chain of the target block (e.g., the block 110-2) may be transmitted to the TDO pin 185 in the form of a TDO signal from the output terminal of the target block (e.g., the block 110-2).

Any or all of the elements described with reference to FIGS. 1-3, 5, 6, and 8-14 may communicate with any or all other elements described with reference to FIGS. 1-3, 5, 6, and 8-14. For example, any element may engage in one-way and/or two-way and/or broadcast communication with any or all other elements in any of the figures, to transfer and/or exchange and/or receive information such as but not limited to data and/or commands, such as in a serial and/or parallel manner, via a bus such as a wireless and/or a wired bus. The information may be in encoded various formats, such as in an analog format and/or in a digital format, without being limited thereto.

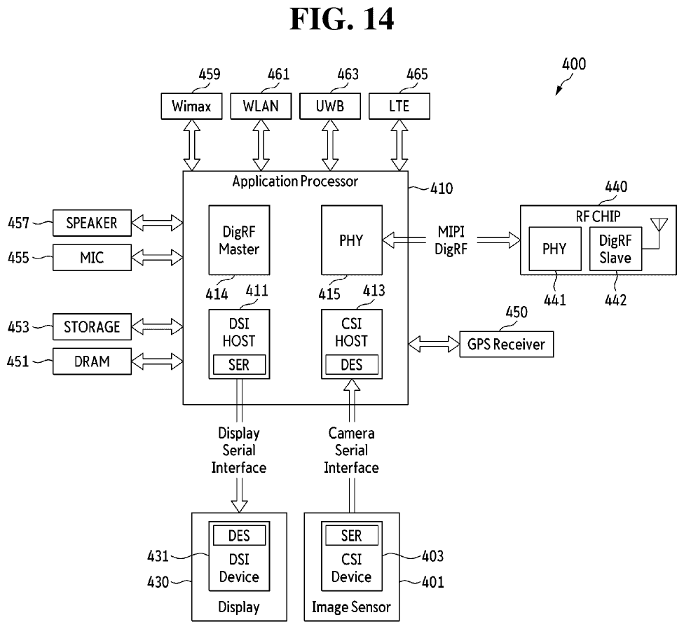

FIG. 14 is a diagram illustrating an electronic system that includes a system on chip according to some example embodiments.

An electronic system 400, which includes the system on chip 100 shown in FIG. 1, may be implemented as a portable electronic device capable of using or supporting a mobile industry processor interface (MIPI®). The portable electronic device may be implemented as a smartphone, a tablet PC, or a mobile Internet device.

The electronic system 400 may include an application processor (AP) 410, an image sensor 401, and a display 430. The AP 410 of FIG. 14 may be implemented as the system on chip 100 shown in FIG. 1.

A camera serial interface (CSI) host 413 implemented in the AP 410 may perform serial communication with the CSI device 403 of the image sensor 401 through a camera serial interface CSI.

According to some example embodiments, a de-serializer DES may be implemented in the CSI host 413, and a serializer SER may be implemented in the CSI device 403. A display serial interface (DSI) host 411 implemented in the AP 410 may perform serial communication with the DSI device 431 of the display 430 through a display serial interface.

According to some example embodiments, the serializer SER may be implemented in the DSI host 411, and the de-serializer DES may be implemented in the DSI device 431. Each of the de-serializer DES and the serializer SER may process an electrical signal or an optical signal.

The electronic system 400 may further include a radio frequency (RF) chip 440 capable of performing communication with the AP 410. A physical layer (PHY) 415 of the AP 410 and a PHY 441 of the RF chip 440 may exchange data in accordance with MIPI DigRF. The AP 410 may include a DigRF Master 414 that initiates and controls communication, whereas the RF chip 440 may include a DigRF Slave 442 that responds to commands and exchanges RF data accordingly.

The electronic system 400 may further include a GPS receiver 450, a memory 451, a data storage 453, a microphone 455, and/or a speaker 457. The memory 451 and the data storage 453 may be a “computer readable medium or media” that stores computer readable program code for execution by the AP 410. Such a medium may take many forms, including, but not limited to, non-volatile media and volatile media. Non-volatile media include, for example, optical disks, magnetic disks, or flash memory (e.g., NAND flash memory). Volatile media include dynamic memory, such as a dynamic random access memory (DRAM). Other forms of machine-readable media include, for example, floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH EPROM, any other memory chip or cartridge, or any other medium from which a processor (or computer) can read.

The electronic system 400 may perform communication with an external device by using at least one communication protocol (or communication standard), such as worldwide interoperability for microwave access (WiMAX) 459, Wireless LAN (WLAN) 461, ultra-wideband (UWB) 463, or long term evolution (LTE) 465.

The electronic system 400 may perform communication with an external wireless communication device by using Bluetooth or WiFi.

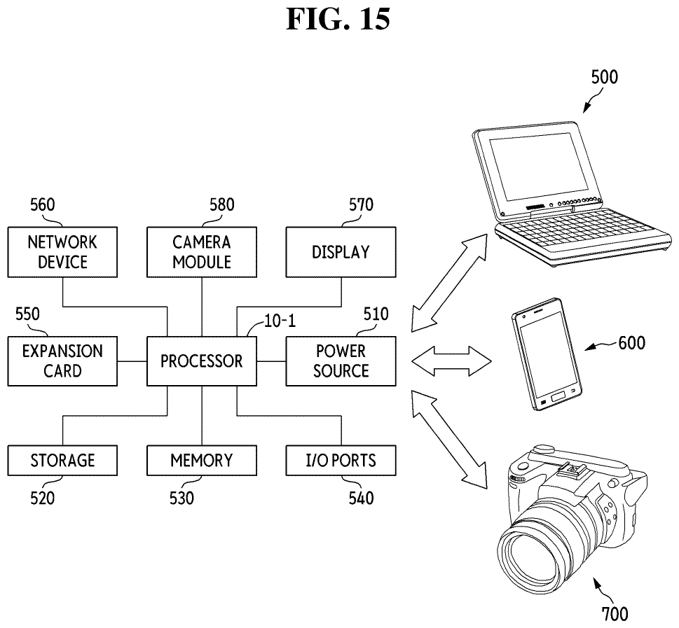

FIG. 15 is a diagram illustrating an electronic system that includes a system on chip according to some example embodiments.

An electronic system 500, 600 or 700 may be implemented as a personal computer (PC), a data server or a portable electronic device. For example, the electronic system 500 may be implemented as a laptop computer, the electronic system 600 may be implemented as a smartphone or a tablet PC, and the electronic system 700 may be implemented as a digital camera.

Each electronic system 500, 600 or 700 is merely an example, and each electronic system 500, 600 or 700 may be implemented as a portable electronic device as follows.

The portable electronic device may be implemented as a laptop computer, a mobile phone, a smartphone, a tablet PC, a personal digital assistant (PDA), an enterprise digital assistant (EDA), a digital still camera, a digital video camera, a portable multimedia player (PMP), a personal navigation device (PND), a handheld game console, a mobile Internet device (MID) or an e-book.

The electronic system 500, 600 or 700 includes a processor 10-1, a power source 510, a storage 520, a memory 530, input/output ports 540, an expansion card 550, a network device 560, and/or a display 570.

The electronic system 500, 600 or 700 may further include a camera module 580. The processor 10-1 may include the system on chip 100 shown in FIG. 1. The processor 10-1 may be a multi-core processor.

The processor 10-1 may control an operation of at least one of elements 510 to 580. The power source 510 may supply an operating voltage to at least one of the elements 10-1 and 520 to 580. The storage 520 may be implemented as a hard disk drive or a solid state drive (SSD). The memory 530 may be implemented as a non-volatile memory capable of storing a program code capable of controlling the operation of the processor 10-1 or as a volatile memory capable of storing data.

For example, the non-volatile memory may be a flash memory, an embedded multimedia card (eMMC), or a universal flash storage (UFS). Also, the volatile memory may be a dynamic random access memory (DRAM).

According to some example embodiments, a memory controller capable of controlling a data access operation (e.g., a read operation, a write operation, or a program operation), or an erase operation for the memory 530 may be integrated or embedded in the processor 10-1.

According to some example embodiments, the memory controller may be implemented between the processor 10-1 and the memory 530.

Input/output ports 540 may refer to ports capable of transmitting data to the electronic system 500, 600 or 700 or transmitting data output from the electronic system 500, 600 or 700 to an external device. For example, the input/output ports 540 may be a port for access of a pointing device such as a computer mouse and a touch pad, a port for access of an output device such as the display 570 or a printer, a port for access of an input device such as a keypad or a keyboard, or a port for access of a USB flash drive.

The expansion card 550 may be implemented as a secure digital (SD) card, a multimedia card (MMC), or an eMMC. According to some example embodiments, the expansion card 550 may be a subscriber identity module (SIM) card or a universal subscriber identity module (USIM) card.

The network device 560 may refer to a device capable of connecting the electronic system 500, 600 or 700 to a wired or wireless network for communication between the electronic system 500, 600 or 700 with the outside.

The display 570 may display data output from the storage 520, the memory 530, the input/output ports 540, the expansion card 550 or the network device 560.

The camera module 580 may refer to a module capable of converting an optical image into an electrical image. Accordingly, the electrical image output from the camera module 580 may be stored in the storage 520, the memory 530 or the expansion card 550. Also, the electrical image output from the camera module 580 may be displayed through the display 570.

As described herein, any devices, systems, modules, portions, units, controllers, circuits, and/or portions thereof according to any of the example embodiments, and/or any portions thereof (including, without limitation, the JTAG interface 180, the JTAG port 140, the power management unit 120, the clock management unit 130, the TAP controller 170, the instruction register 150, the data register 160, the debugger 200, the response server 300, the plurality of blocks 110-1 to 110-n, the alive block BLK_A, the test mode block 210, the electronic system 400, the application processor (AP) 410, the image sensor 401, and the display 430, the camera serial interface (CSI) host 413, the display serial interface (DSI) host 411, the radio frequency (RF) chip 440, the physical layer (PHY) 415, the DigRF Master 414, the DigRF Slave 442, the GPS receiver 450, the microwave access (WiMAX) 459, the Wireless LAN (WLAN) 461, the ultra-wideband (UWB) 463, the long term evolution (LTE) 465, the processor 10-1, the power source 510, the storage 520, the memory 530, the input/output ports 540, the expansion card 550, the network device 560, the display 570, and the camera module 580, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A system on chip, comprising:
a plurality of blocks each including an input terminal and an output terminal and each including a plurality of synchronization circuits connected by a scan-chain;
a test data in (TDI) line;
a test data out (TDO) line connected to the output terminal;
a test access port (TAP) controller configured to control an operation of the plurality of blocks based on a TDI signal input to the TDI line, a TDO signal input to the TDO line, a test clock (TCK) signal, a test reset (TRST) signal and a test mode select (TMS) signal;
a power management unit configured to control power gating for the plurality of blocks; and
a clock management unit configured to control a clock signal provided to the plurality of blocks, wherein
the TAP controller includes a first register that is configured to store a first data for generating a first control signal, the first control signal being configured to control the power management unit and the clock management unit, and
the power management unit and the clock management unit are configured to control the operation of the plurality of blocks based on the first control signal received from the TAP controller.

2. The system on chip of claim 1, wherein the power management unit is configured to turn on power to the plurality of blocks based on the first control signal received from the TAP controller, and
the clock management unit is configured to stop the clock signal provided to the plurality of blocks based on the first control signal received from the TAP controller.

3. The system on chip of claim 1, wherein the TAP controller further includes a second register that is configured to store a second data for generating a second control signal, the second control signal being configured to control the operation of the plurality of blocks,
the TAP controller is configured to select a target block to perform a scan-dump method from the plurality of blocks based on the second control signal, and
the second data is different from the first data.

4. The system on chip of claim 3, wherein the TAP controller further includes a third register that is configured to store a third data for generating a third control signal, the third control signal being configured to control the operation of the plurality of blocks,
the TAP controller is configured to transmit a scan-dump enable signal for setting the plurality of blocks to a scan-dump mode to the plurality of blocks based on the third control signal,
the TAP controller is configured to shift out values loaded into the scan-chain of the target block based on the scan-dump enable signal, and
the third data is different from each of the first data and the second data.

5. The system on chip of claim 4, wherein the TAP controller further includes a fourth register that is configured to store a fourth data for generating a fourth control signal, the fourth control signal being configured to control the operation of the target block,
the TAP controller is configured to output the values shifted out from the scan-chain of the target block through the TDO line connected to the output terminal of the target block based on the fourth control signal, and
the fourth data is different from each of the first data, the second data and the third data.

6. The system on chip of claim 1, further comprising an alive block is configured to control the operation of the plurality of blocks,
wherein the alive block includes:
the power management unit; and
the clock management unit.

7. The system on chip of claim 6, wherein the alive block further includes a Joint Test Action Group (JTAG) pad that is configured to transmit a signal output from the output terminal to the TDO line.

8. The system on chip of claim 6, wherein the alive block further includes:
a pad configured to receive a test mode enable signal for entering a test mode; and
a latch circuit configured to receive the test mode enable signal.

9. A system on chip, comprising:
a plurality of blocks each including an input terminal and an output terminal and each including a plurality of synchronization circuits connected by a scan-chain;
a power management unit configured to control power gating for the plurality of blocks;
a clock management unit configured to control a clock signal provided to the plurality of blocks; and
a test access port (TAP) controller configured to control an operation of the plurality of blocks based on a test data in (TDI) signal synchronized with a test clock (TCK) signal and a test mode select (TMS) signal, and including a first register configured to store a first data for controlling the power management unit and the clock management unit, wherein
the TAP controller is configured to generate a first control signal, the first control signal being configured to control the power management unit and the clock management unit based on the TMS signal and the first data,
the power management unit is configured to turn on power to the plurality of blocks based on the first control signal, and
the clock management unit is configured to stop the clock signal provided to the plurality of blocks based on the first control signal.

10. The system on chip of claim 9, further comprising a Joint Test Action Group (JTAG) interface including a TDI pin to which the TDI signal is input, a test data out (TDO) pin to which a TDO signal is output, a TCK pin to which the TCK signal is input, and a TMS pin to which the TMS signal is input.

11. The system on chip of claim 10, wherein the TAP controller further includes a second register that is configured to store a second data different from the first data,
the TAP controller is configured to generate a second control signal, the second control signal being configured to control the operation of the plurality of blocks based on the TDI signal and the second data, and
the TAP controller is configured to select a target block to perform a scan-dump method from the plurality of blocks based on the second control signal.

12. The system on chip of claim 11, wherein the TAP controller further includes a third register that is configured to store a third data different from each of the first data and the second data,
the TAP controller is configured to generate a third control signal, the third control signal being configured to control the operation of the plurality of blocks based on the third data, and
the TAP controller is configured to transmit a scan-dump enable signal for setting the plurality of blocks to a scan-dump mode to the plurality of blocks based on the third control signal.

13. The system on chip of claim 12, wherein the TAP controller is configured to shift out values loaded into the scan-chain of the target block based on the scan-dump enable signal,
the TAP controller further includes a fourth register that stores a fourth data different from each of the first data, the second data and the third data,
the TAP controller is configured to generate a fourth control signal, the fourth control signal being configured to control the operation of the target block based on the fourth data, and
the TAP controller is configured to output the values shifted out from the scan-chain of the target block to the TDO pin through the output terminal of the target block based on the fourth control signal.

14. The system on chip of claim 13, further comprising an alive block configured to control the operation of the plurality of blocks,
wherein the alive block further includes a Joint Test Action Group (JTAG) pad that is configured to transmit out of the system on chip the values shifted out from the scan-chain of the target block, wherein the values shifted out from the scan-chain of the target block are output from the output terminal of the target block.

15. The system on chip of claim 14, wherein the alive block further includes:
the power management unit; and
the clock management unit.

16. A debugging method for a system on chip comprising a plurality of blocks each including an input terminal and an output terminal and each including a plurality of synchronization circuits connected by a scan-chain, the debugging method comprising:
receiving, by a test access port (TAP) controller, a debugging request signal;
transmitting, by the TAP controller, a first control signal generated based on a test mode selection (TMS) signal and a first data to a power management unit and a clock management unit based on the debugging request signal;
turning on power provided to the plurality of blocks based on the first control signal by the power management unit; and
stopping all clock signals provided to the plurality of blocks based on the first control signal by the clock management unit,
wherein the TAP controller includes a first register that stores first data for controlling the power management unit and the clock management unit.

17. The debugging method of claim 16, further comprising:
generating, by the TAP controller, a second control signal for controlling an operation of the plurality of blocks based on a test data in (TDI) signal and a second data different from the first data; and
selecting, by the TAP controller, a target block to perform a scan-dump method from the plurality of blocks based on the second control signal,
wherein the TAP controller further includes a second register storing the second data.

18. The debugging method of claim 17, further comprising:
generating, by the TAP controller, a third control signal for controlling the operation of the plurality of blocks based on a third data different from each of the first data and the second data;
transmitting, by the TAP controller, a scan-dump enable signal for setting the plurality of blocks to a scan-dump mode to the plurality of blocks based on the third control signal; and
shifting out, by the TAP controller, values loaded into the scan-chain of the target block based on the scan-dump enable signal.

19. The debugging method of claim 18, further comprising:
generating, by the TAP controller, a fourth control signal for controlling the operation of the target block based on a fourth data different from each of the first data, the second data and the third data; and
outputting, by the TAP controller, the values shifted out from the scan-chain of the target block through a TDO line connected to the output terminal of the target block based on the fourth control signal.

20. The debugging method of claim 19, wherein the system on chip further includes a Joint Test Action Group (JTAG) pad, and the debugging method further comprises transmitting, by the JTAG pad, a signal output from the output terminal of the plurality of blocks to the TDO line, and
transmitting, by the JTAG pad, the values shifted out from the scan-chain of the target block to the TDO line.
